(19) United States
(12) Patent Application Publication
(10) Pub. No.: US 2026/0333905 A1
(43) Pub. Date: Oct. 22, 2026

(54) PHOTOELECTRIC CONVERSION DEVICE

(71) Applicant: CANON KABUSHIKI KAISHA, Tokyo (JP)

(72) Inventors: HIROMASA TSUBOI, Tokyo (JP); SHUHEI HAYASHI, Kanagawa (JP)

(21) Appl. No.: 19/632,881

(22) Filed: Mar. 30, 2026

(30) Foreign Application Priority Data
Apr. 17, 2025 (JP) 2025-068396

(51) Int. Cl. H10F 39/00

(52) U.S. Cl. CPC H10F 39/80373; H10F 39/811

(57) ABSTRACT

A photoelectric conversion device includes a semiconductor substrate, a first photoelectric conversion unit formed in an active region of the semiconductor substrate, a plurality of transistors formed in the semiconductor substrate, and a floating diffusion formed in the semiconductor substrate. The plurality of transistors include a first transfer transistor configured to transfer charges from the first photoelectric conversion unit to the floating diffusion, and a switching transistor that is electrically connected to the floating diffusion and is different from the first transfer transistor. In a plan view, an end portion of a first semiconductor region constituting a main electrode of the first transfer transistor on a side of the floating diffusion is located between a gate electrode of the first transfer transistor and a gate electrode of the switching transistor.

### BACKGROUND

### Field of the Technology

The present disclosure relates to a photoelectric conversion device.

### Description of the Related Art

Japanese Patent Laid-Open No. 2010-103667 discloses a solid-state imaging device in which pixels each including a reset transistor and a transfer transistor are arranged.

### SUMMARY

According to one aspect of the present disclosure, there is provided a photoelectric conversion device including a semiconductor substrate, a first photoelectric conversion unit formed in an active region of the semiconductor substrate, a plurality of transistors formed in the semiconductor substrate, and a floating diffusion formed in the semiconductor substrate. The plurality of transistors include a first transfer transistor configured to transfer charges from the first photoelectric conversion unit to the floating diffusion, and a switching transistor that is electrically connected to the floating diffusion and is different from the first transfer transistor. In a plan view with respect to the semiconductor substrate, a part of an outer edge of a gate electrode of the first transfer transistor is in contact with a part of an outer edge of the first photoelectric conversion unit. In the plan view, when an intersection point of a straight line connecting the gate electrode of the first transfer transistor and a gate electrode of the switching transistor at a shortest distance and an end portion of the gate electrode of the switching transistor is defined as a first point, and when an intersection point of the straight line and an end portion of the gate electrode of the first transfer transistor is defined as a second point, a third point is between the first point and the second point, the third point being an end portion of a first semiconductor region constituting a main electrode of the first transfer transistor on a side of the floating diffusion, and being an end portion of the active region. In the plan view, when an intersection point of the end portion of the gate electrode of the first transfer transistor and an end portion of the first photoelectric conversion unit is defined as a fourth point, and when a shortest portion between the second point and the fourth point in the outer edge of the gate electrode of the first transfer transistor is defined as a first outer edge portion, the first outer edge portion does not overlap with an isolation portion that is arranged outside the active region and that electrically separates the first photoelectric conversion unit from other elements. In the plan view, when a point closest to the fourth point in an end portion of the active region is defined as a fifth point, and when a shortest portion between the third point and the fifth point in the outer edge of the active region is defined as a second outer edge portion, a shortest distance between the first outer edge portion and the second outer edge portion is shorter than a distance between the second point and the third point.

According to one aspect of the present disclosure, there is provided a photoelectric conversion device including a semiconductor substrate, a first photoelectric conversion unit formed in an active region of the semiconductor substrate, a plurality of transistors formed in the semiconductor substrate, and a floating diffusion formed in the semiconductor substrate. The plurality of transistors include a first transfer transistor configured to transfer charges from the first photoelectric conversion unit to the floating diffusion, and a switching transistor that is electrically connected to the floating diffusion and is different from the first transfer transistor. In a plan view with respect to the semiconductor substrate, a part of an outer edge of a gate electrode of the first transfer transistor overlaps a part of an outer edge of the first photoelectric conversion unit. In the plan view, when an intersection point of a straight line connecting the gate electrode of the first transfer transistor and a gate electrode of the switching transistor at a shortest distance and an end portion of the gate electrode of the switching transistor is defined as a first point, and when an intersection point of the straight line and an end portion of the gate electrode of the first transfer transistor is defined as a second point, a third point is between the first point and the second point, the third point being an end portion of a first semiconductor region constituting a main electrode of the first transfer transistor on a side of the floating diffusion, and being an end portion of the active region. In the plan view, when an intersection point of the end portion of the gate electrode of the first transfer transistor and an end portion of the first photoelectric conversion unit is defined as a fourth point, and when a shortest portion between the second point and the fourth point in the outer edge of the gate electrode of the first transfer transistor is defined as a first outer edge portion, at least a part of the first outer edge portion overlaps with an isolation portion that is arranged outside the active region and that electrically separates the first photoelectric conversion unit from other elements.

Features of the present disclosure will become apparent from the following description of embodiments with reference to the attached drawings. The following description of embodiments is described by way of example.

### BRIEF DESCRIPTION OF THE DRAWINGS

FIG. 1 is a block diagram illustrating an overall configuration example of a photoelectric conversion device according to a first embodiment.

FIG. 2 is a circuit diagram illustrating a configuration example of a pixel according to the first embodiment.

FIG. 3 is a plan view illustrating a configuration example of the pixel according to the first embodiment.

FIG. 4 is a cross-sectional view illustrating a configuration example of the pixel according to the first embodiment.

FIG. 5 is a cross-sectional view illustrating a configuration example of the pixel according to the first embodiment.

FIG. 6 is a plan view illustrating a configuration example of a pixel according to a second embodiment.

FIG. 7 is a cross-sectional view illustrating a configuration example of the pixel according to the second embodiment.

FIGS. 8A and 8B are plan views illustrating configuration examples of a pixel according to a third embodiment.

FIG. 9 is a circuit diagram illustrating a configuration example of a pixel according to a fourth embodiment.

FIGS. 10A and 10B are plan views illustrating configuration examples of the pixel according to the fourth embodiment.

FIGS. 11A and 11B are cross-sectional views illustrating configuration examples of the pixel according to the fourth embodiment.

FIG. 12 is a circuit diagram illustrating a configuration example of a pixel according to a fifth embodiment.

FIGS. 13A and 13B are plan views illustrating configuration examples of the pixel according to the fifth embodiment.

FIG. 14 is a circuit diagram illustrating a configuration example of a pixel according to a sixth embodiment.

FIGS. 15A and 15B are plan views illustrating configuration examples of the pixel according to the sixth embodiment.

FIGS. 16A and 16B are plan views illustrating configuration examples of a pixel according to a seventh embodiment.

FIG. 17 is a circuit diagram illustrating a configuration example of a pixel according to an eighth embodiment.

FIG. 18 is a plan view illustrating a configuration example of the pixel according to the eighth embodiment.

FIG. 19 is a cross-sectional view illustrating a configuration example of the pixel according to the eighth embodiment.

FIG. 20 is a plan view illustrating a configuration example of the pixel according to a modification of the eighth embodiment.

FIG. 21 is a block diagram illustrating a schematic configuration of equipment according to a ninth embodiment.

FIGS. 22A and 22B are block diagrams illustrating a schematic configuration of equipment according to a tenth embodiment.

### DESCRIPTION OF THE EMBODIMENTS

In a photoelectric conversion device including a transistor other than a transfer transistor as disclosed in Japanese Patent Laid-Open No. 2010-103667, signal quality may degrade due to a dark current that may be generated when the transistor is turned on. The following disclosure relates to a photoelectric conversion device with improved signal quality.

Hereinafter, embodiments will be described in detail with reference to the accompanying drawings. Note that the following embodiments do not limit the technology according to the claims. Although a plurality of features are described in the embodiments, not all of the plurality of features are essential to the claimed technology. Further, the plurality of features may be combined as appropriate. Throughout the drawings, the same or corresponding elements are denoted by the same reference numerals, and redundant description thereof may be omitted or simplified.

In the embodiments described below, an imaging device will be mainly described as an example of a photoelectric conversion device. However, the photoelectric conversion device in each embodiment is not limited to the imaging device, and can be applied to other photodetection devices based on photoelectric conversion. Examples of other photodetection devices include a ranging device and a photometric device. The ranging device may be, for example, a focus detection device, a distance measuring device using time-of-flight (TOF), or the like. The photometric device may be a device that measures the amount of light incident on the device.

Hereinafter, a semiconductor region of a first conductivity type having the same carriers as the signal carriers as the majority carriers is an N-type semiconductor region, and a semiconductor region of a second conductivity type is a P-type semiconductor region. That is, the signal carriers are electrons. In addition, an anode of a photodiode constituting a photoelectric conversion unit is of an N-type, and a cathode of the photodiode is of a P-type. The polarity and the conductivity type may be opposite to those described above. That is, the signal carriers may be holes, the semiconductor region of the first conductivity type may be the P-type semiconductor region, and the semiconductor region of the second conductivity type may be the N-type semiconductor region. The anode of the photodiode constituting the photoelectric conversion unit may be the P-type, and the cathode of the photodiode may be the N-type. In this case, the voltage relationship is also reversed.

### First Embodiment

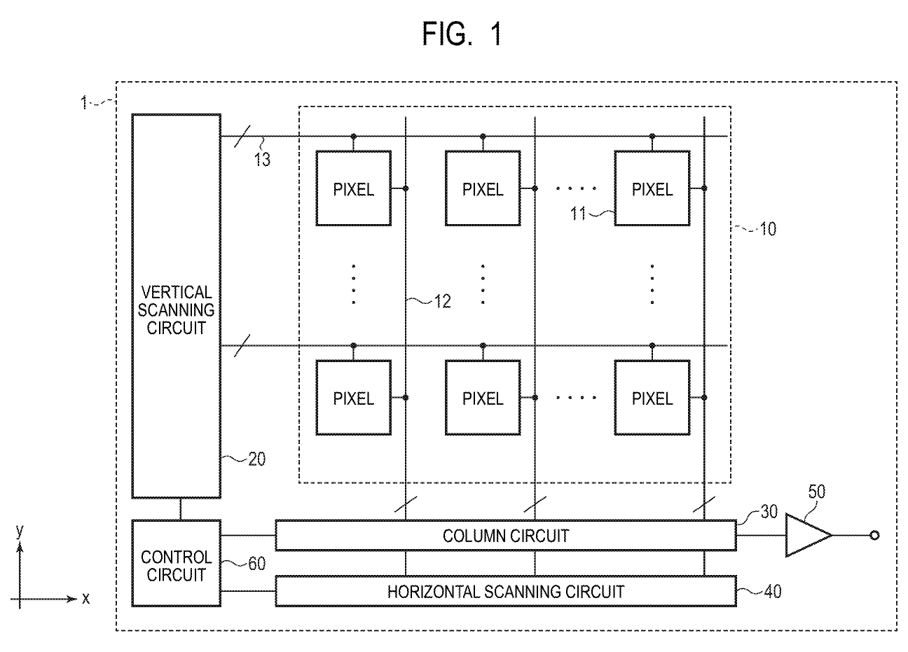

FIG. 1 is a block diagram illustrating an overall configuration example of a photoelectric conversion device 1 according to the present embodiment. The photoelectric conversion device 1 includes a pixel array 10, a vertical scanning circuit 20, a column circuit 30, a horizontal scanning circuit 40, an output circuit 50, and a control circuit 60. The pixel array 10 includes a plurality of pixels 11 arranged in an x direction and a y direction and forming a plurality of rows and a plurality of columns. The vertical scanning circuit 20, the column circuit 30, the horizontal scanning circuit 40, the output circuit 50, and the control circuit 60 are driving circuits of the photoelectric conversion device 1.

In the pixel array 10, a scanning line 13 is arranged for each row, and an output signal line 12 is arranged for each column. The scanning line 13 is connected to the vertical scanning circuit 20, and the output signal line 12 is connected to the column circuit 30. Although one signal line is illustrated in one row as the scanning line 13 in FIG. 1, the scanning line 13 in one row may include a plurality of signal lines. The plurality of signal lines supply different control signals to the pixels 11. Although one output signal line 12 is illustrated in one column in FIG. 1, a plurality of output signal lines 12 may be arranged in one column.

In FIG. 1, the drive circuit is arranged around the pixel array 10. However, the position where the driving circuit is arranged is not limited thereto. For example, in a case where the photoelectric conversion device 1 is a stacked type in which a plurality of semiconductor substrates are stacked, the drive circuit unit may be arranged in a region overlapping the pixel array 10 in a plan view. Note that, in this specification, the plan view refers to viewing a surface parallel to a light incident surface of a substrate including the photoelectric conversion unit from a normal direction of the surface parallel to the light incident surface.

Each of the plurality of pixels 11 converts light into an electrical signal. Each of the plurality of pixels 11 outputs the generated electrical signal to the column circuit 30 via the output signal line 12 of the corresponding column.

The control circuit 60 supplies, to the vertical scanning circuit 20, the column circuit 30, and the horizontal scanning circuit 40, control signals for controlling operation timings and the like of the respective units. The vertical scanning circuit 20 outputs control signals for controlling the pixels 11 for each row via the scanning line 13. The vertical scanning circuit 20 performs scanning for sequentially selecting the pixels 11 in each row, and outputting signals from the selected pixels 11 to the output signal lines 12.

The column circuit 30 performs signal processing on the electrical signal input from the pixel 11 for each column. This signal processing may include, for example, noise removal, signal amplification, and the like.

The horizontal scanning circuit 40 supplies control signals to the column circuit 30 for sequentially outputting the signal processed in the column circuit 30 to the output circuit 50 for each column. The output circuit 50 outputs the signal output from the column circuit 30 to the outside of the photoelectric conversion device 1. A device to which the signal output from the photoelectric conversion device 1 is input may be, for example, a storage device or a signal processing device.

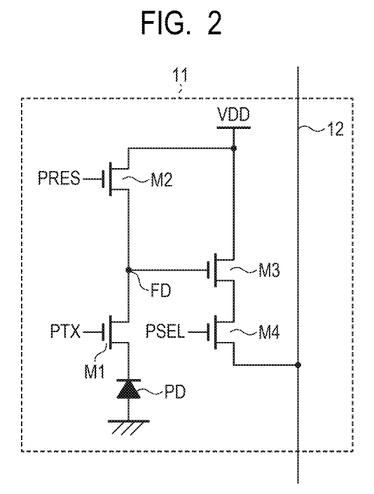

FIG. 2 is a circuit diagram illustrating a configuration example of the pixel 11 according to the present embodiment. The pixel 11 includes a photoelectric conversion unit PD, a transfer transistor M1, a reset transistor M2, an amplification transistor M3, and a selection transistor M4. The transfer transistor M1, the reset transistor M2, the amplification transistor M3, and the selection transistor M4 are N-type metal-oxide-semiconductor (MOS) transistors. A drain and a source of each transistor may be collectively referred to as main electrodes. The reset transistor M2 and a capacitance addition transistor described later may be collectively referred to as switching transistors.

The photoelectric conversion unit PD (first photoelectric conversion unit) is a photoelectric conversion element that generates and accumulates charges according to incident light by photoelectric conversion. The photoelectric conversion unit PD is typically a photodiode.

An anode of the photoelectric conversion unit PD is connected to a ground line having a ground potential. A cathode of the photoelectric conversion unit PD is connected to a source of the transfer transistor M1 (first transfer transistor). A drain of the transfer transistor M1 is connected to a source of the reset transistor M2 and a gate of the amplification transistor M3. A connection node between the drain of the transfer transistor M1, the source of the reset transistor M2, and the gate of the amplification transistor M3 is a floating diffusion FD. The floating diffusion FD has a parasitic capacitance parasitic to a semiconductor region or the like constituting these transistors, and holds charges transferred from the photoelectric conversion unit PD.

A drain of the reset transistor M2 and a drain of the amplification transistor M3 are connected to a power supply line having a power supply potential VDD. A source of the amplification transistor M3 is connected to a drain of the selection transistor M4. A source of the selection transistor M4 is connected to the output signal line 12.

The vertical scanning circuit 20 supplies a control signal PTX to a gate of the transfer transistor M1 via one signal line constituting the scanning line 13. When the transfer transistor M1 is turned on according to the control signal PTX, the charges accumulated in the photoelectric conversion unit PD is transferred to the floating diffusion FD.

The vertical scanning circuit 20 supplies a control signal PRES to a gate of the reset transistor M2 via one signal line constituting the scanning line 13. When the reset transistor M2 is turned on according to the control signal PRES, the charges transferred to the floating diffusion FD is discharged, and the potential of the floating diffusion FD is reset.

The vertical scanning circuit 20 supplies a control signal PSEL to a gate of the selection transistor M4 via one signal line constituting the scanning line 13. When the selection transistor M4 is turned on according to the control signal PSEL, a signal is output from the amplification transistor M3 in the corresponding row to the output signal line 12. At this time, the amplification transistor M3 and a current source (not illustrated) connected to the output signal line 12 constitute a source follower circuit that outputs a signal corresponding to the charges transferred to the floating diffusion FD, thereby functioning as an amplification unit.

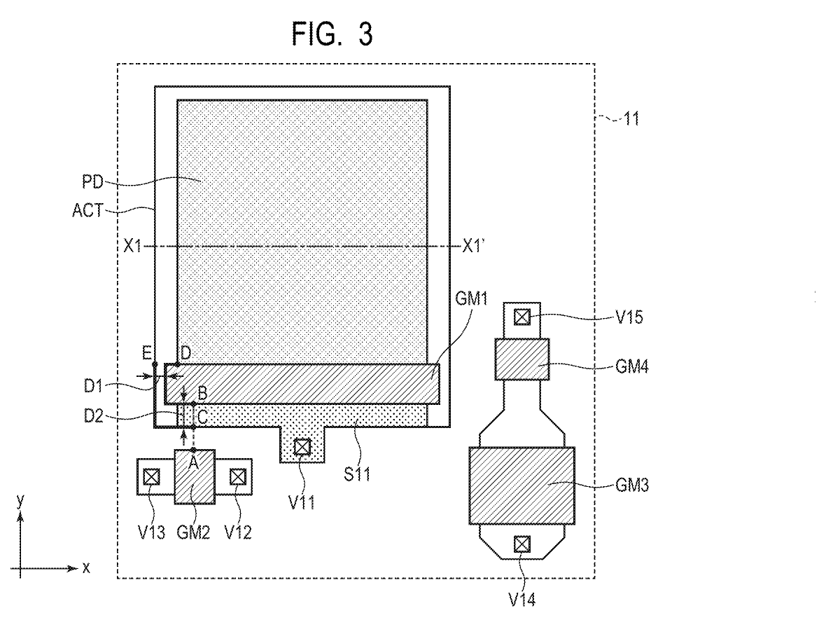

FIG. 3 is a plan view illustrating a configuration example of the pixel 11 according to the present embodiment. FIG. 3 schematically illustrates an arrangement of semiconductor regions, gate electrodes, and vias constituting the photoelectric conversion unit PD, the transfer transistor M1, the reset transistor M2, the amplification transistor M3, and the selection transistor M4 in a plan view.

FIG. 3 illustrates an arrangement of gate electrodes GM1 to GM4, an N-type semiconductor region S11, vias V11 to V15, and an active region ACT. The gate electrodes GM1, GM2, GM3, and GM4 are gates of the transfer transistor M1, the reset transistor M2, the amplification transistor M3, and the selection transistor M4, respectively. The N-type semiconductor region S11 (first semiconductor region) is the drain of the transfer transistor M1. The vias V11 and V12 are electrically connected to the gate electrode GM3 via wiring (not illustrated). This connection node corresponds to the floating diffusion FD illustrated in FIG. 2. The vias V13 and V14 are connected to the power supply voltage node. The via V15 is connected to the output signal line 12. The photoelectric conversion unit PD is formed in the active region ACT. A part of an outer edge of the gate electrode GM1 is in contact with a part of an outer edge of the photoelectric conversion unit PD.

As illustrated in FIG. 3, an end portion of the gate electrode GM2 and an end portion of the gate electrode GM1 at least partially face each other. A line segment AB, which connects a point A (first point) on the end portion of the gate electrode GM2 and a point B (second point) on the end portion of the gate electrode GM1, is one of linear paths connecting both gate electrodes at the shortest distance. An intersection point of an end portion of the N-type semiconductor region S11 and the line segment AB is defined as a point C (third point). The point C is also at an end portion of the active region ACT. Since the point C is located between the point A and the point B, these three points are arranged in the order of the point A, the point C, and the point B along the y direction. With such an arrangement, the region of the N-type semiconductor region S11 that is the drain of the transfer transistor M1 can be enlarged as compared with a case where the gate electrode of the transfer transistor and the gate electrode of another transistor are adjacent to each other. Therefore, since a channel width on the drain side of the transfer transistor M1 can be increased, the charge transfer efficiency of the transfer transistor M1 can be improved.

Further, an intersection point between the end portion of the photoelectric conversion unit PD and the end portion of the gate electrode GM1 is defined as a point D (fourth point), and a shortest path from the point B to the point D along the outer edge of the gate electrode GM1 is defined as a path B-D (first outer edge portion). The end portion of the active region ACT closest to the point D is defined as a point E (fifth point), and the shortest path from the point C to the point E along the outer edge of the active region ACT is defined as a path C-E (second outer edge portion). A distance D1 illustrated in FIG. 3 is the shortest distance between the path B-D and the path C-E. The distance D1 is shorter than a distance D2 between the point B and the point C.

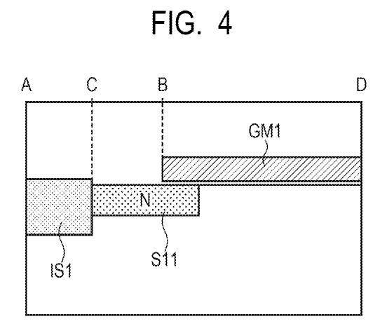

The effect of the distance D1 being shorter than the distance D2 will be described with reference to FIG. 4. FIG. 4 is a cross-sectional view illustrating a configuration example of the pixel 11 according to the present embodiment. FIG. 4 illustrates a cross section of a path from the point A to the point D via the point C and the point B in FIG. 3. As illustrated in FIG. 4, the gate electrode GM1 is arranged over the substrate between the point B and the point D. An isolation portion IS1 is arranged in the vicinity of the substrate between the point A and the point C. The isolation portion IS1 is, for example, an element isolation structure formed of a shallow trench isolation (STI), a local oxidation of silicon (LOCOS), or a P-type semiconductor region.

When the reset transistor M2 is turned on, the hole density decreases in the vicinity of the interface of the isolation portion IS1 between the gate electrode GM2 and the N-type semiconductor region S11, that is, in the vicinity of the point C. As a result, the dark current increases, and noise generated by the dark current flowing into the photoelectric conversion unit PD may degrade the signal quality. However, in the present embodiment, since the distance D1 is shorter than the distance D2, the width of the path through which the dark current flows into the photoelectric conversion unit PD from the vicinity of the point C is narrow. Accordingly, the amount of dark current flowing into the photoelectric conversion unit PD when the reset transistor M2 is turned on can be reduced, and noise can be reduced, so that signal quality can be improved.

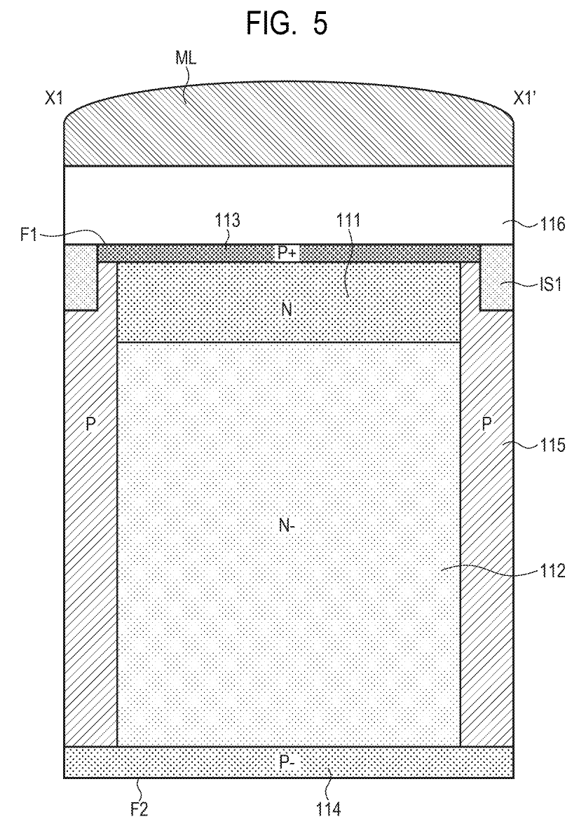

FIG. 5 is a cross-sectional view illustrating a configuration example of the pixel 11 according to the present embodiment. FIG. 5 illustrates a cross section taken along line X1-X1' in FIG. 3. A wiring layer 116 and a microlens ML are arranged over a first face F1 which is a front face of the semiconductor substrate in which the photoelectric conversion device 1 is formed. A second face F2 opposite to the first face F1 is a back face of the semiconductor substrate. That is, the photoelectric conversion device 1 of the present embodiment is a frontside illumination type that receives light incident from the first face F1. However, the structure of the photoelectric conversion device 1 of the present embodiment may be modified to a backside illumination type that receives light incident from the second face F2. An N-type semiconductor region 111 and an N-type semiconductor region 112 are formed in a portion of the photoelectric conversion unit PD in the semiconductor substrate. The N-type semiconductor region 111 is arranged closer to the first face F1 than the N-type semiconductor region 112. A peak concentration of impurity in the N-type semiconductor region 111 is higher than a peak concentration of impurity in the N-type semiconductor region 112.

A P-type semiconductor region 113 is arranged at the first face F1 of the semiconductor substrate, and a P-type semiconductor region 114 is arranged at the second face F2 of the semiconductor substrate. A peak concentration of impurity in the P-type semiconductor region 113 is higher than a peak concentration of impurity in the P-type semiconductor region 114. The P-type semiconductor region 113 suppresses a dark current generated on the first face F1, and the P-type semiconductor region 114 suppresses a dark current generated on the second face F2.

P-type semiconductor region 115 and the isolation portion IS1 are arranged outside the N-type semiconductor regions 111 and 112. The P-type semiconductor region 115 and the isolation portion IS1 electrically isolate adjacent pixels from each other.

As described above, the photoelectric conversion device 1 of the present embodiment has a structure capable of reducing the influence of noise due to the dark current. Therefore, according to the present embodiment, the photoelectric conversion device 1 capable of improving the signal quality is provided.

### Second Embodiment

In the present embodiment, a modification regarding an arrangement of the gate electrode GM1 of the transfer transistor M1 and the isolation portion IS1 will be described. In the present embodiment, description of elements common to those of the first embodiment may be omitted or simplified.

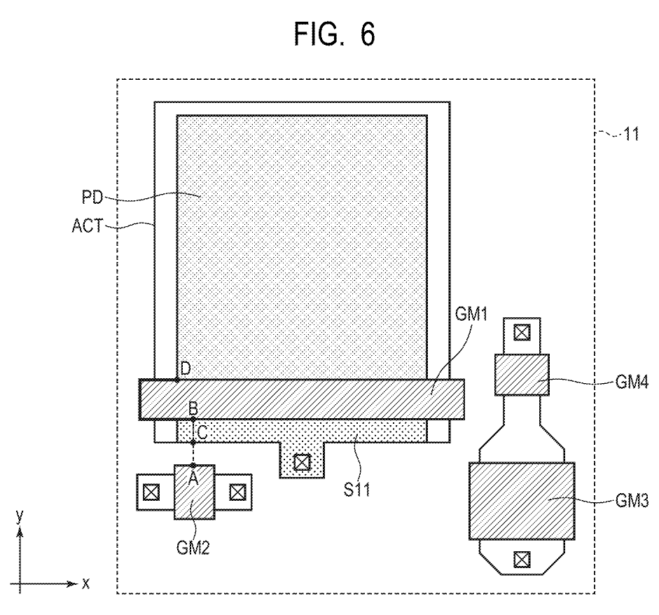

FIG. 6 is a plan view illustrating a configuration example of the pixel 11 according to the present embodiment. While a gap of the distance D1 is provided between the end portion of the gate electrode GM1 and the end portion of the active region ACT in FIG. 3, the end portion of the gate electrode GM1 extends beyond the end portion of the active region ACT in FIG. 6. Therefore, in the present embodiment, the path B-D passes outside the active region ACT, that is, over the isolation portion IS1.

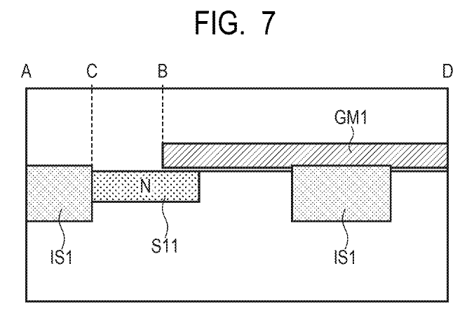

FIG. 7 is a cross-sectional view illustrating a configuration example of the pixel 11 according to the present embodiment. FIG. 7 illustrates a cross section in a path from the point A to the point D via the point C and the point B in FIG. 6. As illustrated in FIG. 7, the gate electrode GM1 is arranged over the substrate between the point B and the point D. The isolation portion IS1 is arranged below a part of the gate electrode GM1. Since the path of the dark current from the vicinity of the point C toward the photoelectric conversion unit PD is blocked, the amount of the dark current flowing into the photoelectric conversion unit PD when the reset transistor M2 is turned on can be reduced, and noise can be reduced. Therefore, also in the present embodiment, similarly to the first embodiment, the photoelectric conversion device 1 capable of improving the signal quality is provided.

### Third Embodiment

In the present embodiment, a modification related to an arrangement of the semiconductor region in the vicinity of the transfer transistor M1 will be described. In the present embodiment, description of elements common to the first embodiment and the second embodiment may be omitted or simplified.

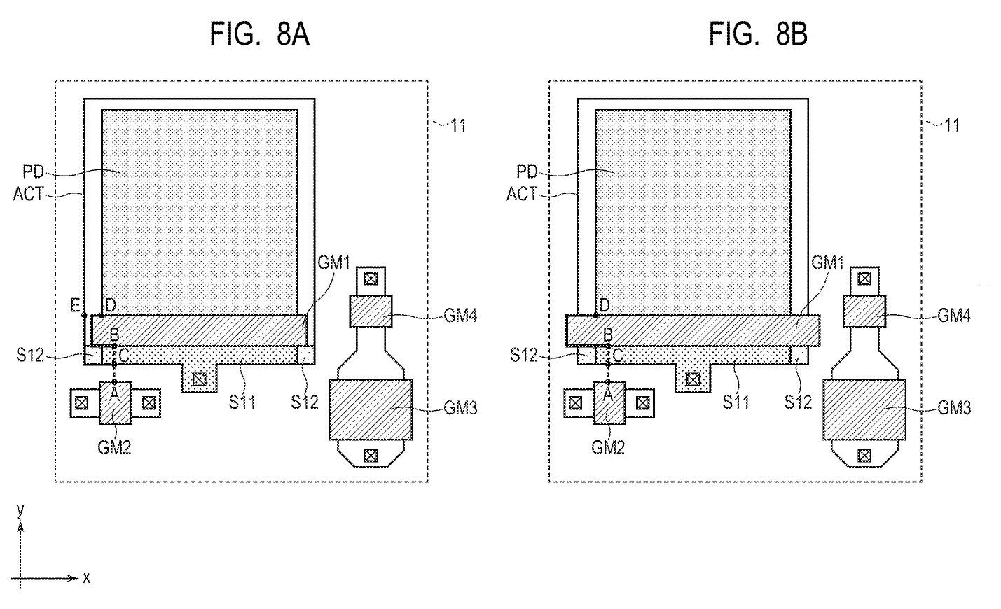

FIG. 8A is a plan view illustrating a configuration example of the pixel 11 according to the present embodiment. In FIG. 8A, in addition to the configuration of FIG. 3 of the first embodiment, a semiconductor region S12 (second semiconductor region) is arranged adjacent to the N-type semiconductor region S11. The semiconductor region S12 is arranged on a path from the N-type semiconductor region S11 toward the photoelectric conversion unit PD in the plan view. The conductivity type of the semiconductor region S12 may be the P-type or the N-type. However, when the conductivity type of the semiconductor region S12 is the N-type, a peak concentration of impurity in the semiconductor region S12 is lower than a peak concentration of impurity in the N-type semiconductor region S11.

When the conductivity type of the semiconductor region S12 is P-type, an electric field in a direction from the N-type semiconductor region S11 toward the semiconductor region S12 is formed by a depletion layer formed in the vicinity of the interface of the N-type semiconductor region S11. The dark electrons generated in the vicinity of the point C flow into the N-type semiconductor region S11 by this electric field. Therefore, the amount of dark current flowing into the photoelectric conversion unit PD when the reset transistor M2 is turned on can be further reduced, and noise can be further reduced.

The same phenomenon as described above also occurs when the conductivity type of the semiconductor region S12 is N-type and the peak concentration of impurity in the semiconductor region S12 is lower than the peak concentration of impurity in the N-type semiconductor region S11. Therefore, the amount of dark current flowing into the photoelectric conversion unit PD when the reset transistor M2 is turned on can be further reduced, and noise can be further reduced. Therefore, according to the present embodiment, the photoelectric conversion device 1 capable of further improving the signal quality is provided.

FIG. 8B is a plan view illustrating a configuration example of the pixel 11 according to a modification of the present embodiment. This modification is an example in which the above-described semiconductor region S12 is applied to the configuration of FIG. 6 of the second embodiment instead of the configuration of FIG. 3 of the first embodiment. As in the case of FIG. 8A, the semiconductor region S12 is arranged adjacent to the N-type semiconductor region S11. Accordingly, the amount of dark current flowing into the photoelectric conversion unit PD when the reset transistor M2 is turned on can be further reduced, and noise can be further reduced. Therefore, the photoelectric conversion device 1 capable of further improving the signal quality is similarly provided in the present modification.

### Fourth Embodiment

In the present embodiment, a modification in which the pixel 11 further includes a capacitance addition transistor will be described. In the present embodiment, description of elements common to the first to third embodiments may be omitted or simplified.

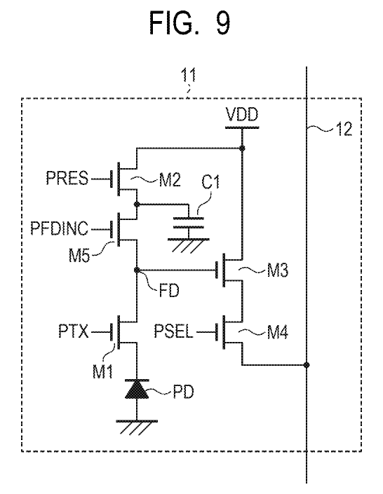

FIG. 9 is a circuit diagram illustrating a configuration example of the pixel 11 according to the present embodiment. The pixel 11 includes a capacitive element C1 and a capacitance addition transistor M5 in addition to the configuration of the first embodiment illustrated in FIG. 2. The capacitive element C1 may be a MOS capacitor or a metal-insulator-metal (MIM) capacitor. The capacitive element C1 may be an interwire capacitance. Hereinafter, the capacitive element C1 is an interwire capacitance formed in the wiring layer and has a first terminal and a second terminal. The capacitance addition transistor M5 is an N-type MOS transistor.

A source of the capacitance addition transistor M5 is connected to the drain of the transfer transistor M1 and the gate of the amplification transistor M3. A connection node between the drain of the transfer transistor M1, the source of the capacitance addition transistor M5, and the gate of the amplification transistor M3 is the floating diffusion FD. A drain of the capacitance addition transistor M5 is connected to the source of the reset transistor M2 and the first terminal of the capacitive element C1. The second terminal of the capacitive element C1 is connected to the ground line having the ground potential. The drain of the reset transistor M2 is connected to the power supply line having the power supply potential VDD.

The vertical scanning circuit 20 supplies a control signal PFDINC to a gate of the capacitance addition transistor M5 via one signal line constituting the scanning line 13. When the capacitance addition transistor M5 is turned on according to the control signal PFDINC, the capacitance of the capacitive element C1 is connected in parallel to the capacitance of the floating diffusion FD, and the substantial capacitance of the floating diffusion FD increases. At this time, as compared with a case where the capacitance addition transistor M5 is in the off state, the conversion efficiency from the charge to the voltage in the floating diffusion FD decreases. Accordingly, for example, it is possible to suppress whiteout of an image when capturing a bright object. As described above, the capacitive element C1 and the capacitance addition transistor M5 have a function of changing the conversion efficiency from the charge to the voltage in the floating diffusion FD.

It should be noted that the location where the capacitive element C1 and the capacitance addition transistor M5 are connected is not limited to that illustrated in FIG. 9. For example, the circuit configuration may be such that the drain of the capacitance addition transistor M5 and the source of the reset transistor M2 are connected to the floating diffusion FD, and the source of the capacitance addition transistor M5 is connected to the first terminal of the capacitive element C1.

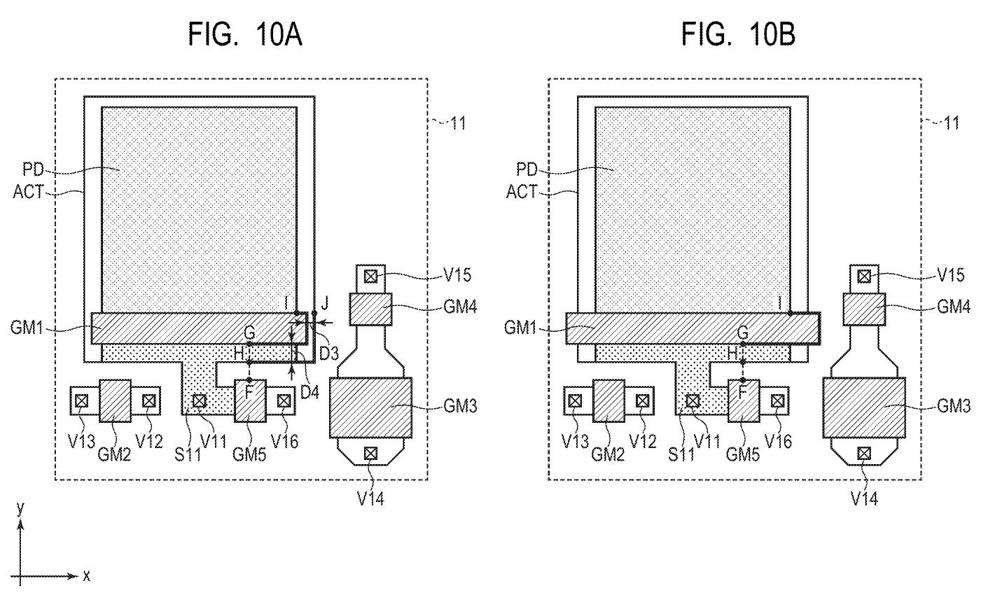

FIG. 10A is a plan view illustrating a configuration example of the pixel 11 according to the present embodiment. FIG. 10A illustrates an arrangement of gate electrodes GM1 to GM5, an N-type semiconductor region S11, vias V11 to V16, and an active region ACT. The gate electrode GM5 is the gate of the capacitance addition transistor M5. The via V11 is electrically connected to the gate electrode GM3 via a wiring (not illustrated). This connection node corresponds to the floating diffusion FD illustrated in FIG. 9. The via V12 and the via V16 are connected to each other via a wiring (not illustrated), and are also connected to the capacitive element C1.

As illustrated in FIG. 10A, an end portion of the gate electrode GM5 and an end portion of the gate electrode GM1 at least partially face each other. A line segment FG, which connects a point F (first point) on the end portion of the gate electrode GM5 and a point G (second point) on the end portion of the gate electrode GM1, is one of linear paths connecting both gate electrodes at the shortest distance. An intersection point of an end of the N-type semiconductor region S11 and the line segment FG is defined as a point H (third point). The point H is also at an end portion of the active region ACT. Since the point H is located between the point F and the point G, these three points are arranged in the order of the point F, the point H, and the point G along the y direction. With such an arrangement, the region of the N-type semiconductor region S11 that is the drain of the transfer transistor M1 can be enlarged as compared with a case where the gate electrode of the transfer transistor and the gate electrode of another transistor are adjacent to each other. Therefore, since a channel width on the drain side of the transfer transistor M1 can be increased, the charge transfer efficiency of the transfer transistor M1 can be improved.

Further, an intersection point between the end portion of the photoelectric conversion unit PD and the end portion of the gate electrode GM1 is defined as a point I (fourth point), and a shortest path from the point G to the point I along the outer edge of the gate electrode GM1 is defined as a path G-I (first outer edge portion). The end portion of the active region ACT closest to the point I is defined as a point J (fifth point), and the shortest path from the point H to the point J along the outer edge of the active region ACT is defined as a path H-J (second outer edge portion). A distance D3 illustrated in FIG. 10A is the shortest distance between the path G-I and the path H-J. The distance D3 is shorter than a distance D4 between the point G and the point H.

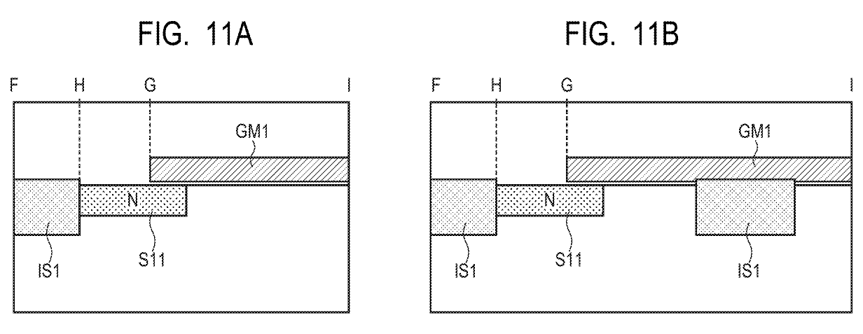

FIG. 11A is a cross-sectional view illustrating a configuration example of the pixel 11 according to the present embodiment. FIG. 11A illustrates a cross section in a path from the point F to the point I via the point H and the point G in FIG. 10A. As illustrated in FIG. 11A, a gate electrode GM1 is arranged over the substrate between the point G and the point I. An isolation portion IS1 is arranged in the vicinity of the substrate between the point F and the point H.

When the capacitance addition transistor M5 is turned on, the hole density decreases in the vicinity of the interface of the isolation portion IS1 between the gate electrode GM5 and the N-type semiconductor region S11, that is, in the vicinity of the point H. As a result, the dark current increases, and noise generated by the dark current flowing into the photoelectric conversion unit PD may degrade the signal quality. However, in the present embodiment, since the distance D3 is shorter than the distance D4, the width of the path through which the dark current flows into the photoelectric conversion unit PD from the vicinity of the point H is narrow. Accordingly, the amount of dark current flowing into the photoelectric conversion unit PD when the capacitance addition transistor M5 is turned on can be reduced, and noise can be reduced, so that signal quality can be improved. Therefore, also in the present embodiment, similarly to the first embodiment, the photoelectric conversion device 1 capable of improving the signal quality is provided.

Next, a modification in which an arrangement of the gate electrode GM1 of the transfer transistor M1 and the isolation portion IS1 is modified to a similar configuration as that of the second embodiment will be described. FIG. 10B is a plan view illustrating a configuration example of the pixel 11 according to the modification of the present embodiment. While a gap of the distance D3 is provided between the end portion of the gate electrode GM1 and the end portion of the active region ACT in FIG. 10A, the end portion of the gate electrode GM1 extends beyond the end portion of the active region ACT in FIG. 10B. Therefore, in the present modification, the path G-I passes outside the active region ACT, that is, over the isolation portion IS1.

FIG. 11B is a cross-sectional view illustrating a configuration example of the pixel 11 according to the modification of the present embodiment. FIG. 11B illustrates a cross section in a path from the point F to the point I via the point H and the point G in FIG. 10B. As illustrated in FIG. 11B, a gate electrode GM1 is arranged over the substrate between the point G and the point I. The isolation portion IS1 is arranged below at least a part of the gate electrode GM1. Since the path of the dark current from the vicinity of the point H toward the photoelectric conversion unit PD is blocked, the amount of the dark current flowing into the photoelectric conversion unit PD when the capacitance addition transistor M5 is turned on can be reduced, and noise can be reduced. Therefore, also in the present modification, the photoelectric conversion device 1 capable of improving the signal quality is provided.

### Fifth Embodiment

In the present embodiment, a modification in which the pixel 11 includes two photoelectric conversion units and two transfer transistors will be described. In the present embodiment, description of elements common to the first to fourth embodiments may be omitted or simplified.

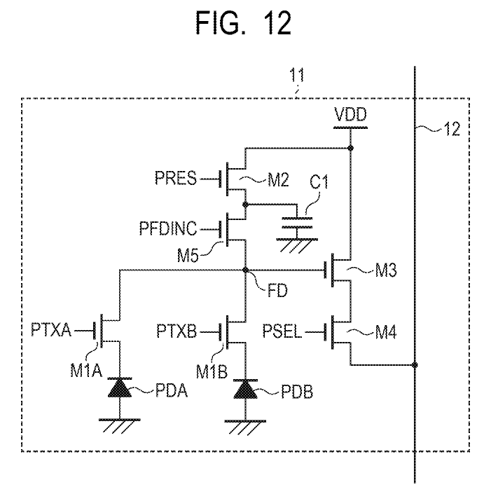

FIG. 12 is a circuit diagram illustrating a configuration example of the pixel 11 according to the present embodiment. The pixel 11 of the present embodiment includes two photoelectric conversion units PDA and PDB (first photoelectric conversion unit and second photoelectric conversion unit) and two transfer transistors M1A and M1B (first transfer transistor and second transfer transistor). This point of the pixel 11 of the present embodiment is different from the pixel 11 of FIG. 9 of the fourth embodiment. Anodes of the photoelectric conversion units PDA and PDB are connected to the ground line having the ground potential. A cathode of the photoelectric conversion unit PDA is connected to a source of the transfer transistor M1A, and a cathode of the photoelectric conversion unit PDB is connected to a source of the transfer transistor M1B. Drains of the transfer transistors M1A and M1B are connected to the source of the capacitance addition transistor M5 and the gate of the amplification transistor M3. A connection node between the drains of the transfer transistors M1A and M1B, the source of the capacitance addition transistor M5, and the gate of the amplification transistor M3 is the floating diffusion FD.

The vertical scanning circuit 20 supplies a control signal PTXA to a gate of the transfer transistor M1A via one signal line constituting the scanning line 13. When the transfer transistor M1A is turned on according to the control signal PTXA, charges accumulated in the photoelectric conversion unit PDA is transferred to the floating diffusion FD. Further, the vertical scanning circuit 20 supplies a control signal PTXB to a gate of the transfer transistor M1B via another signal line constituting the scanning line 13. When the transfer transistor M1B is turned on according to the control signal PTXB, charges accumulated in the photoelectric conversion unit PDB is transferred to the floating diffusion FD.

As described above, in the present embodiment, the two photoelectric conversion units PDA and PDB share the reset transistor M2, the amplification transistor M3, the selection transistor M4, and the capacitance addition transistor M5. That is, the number of transistors per photoelectric conversion unit (the ratio of the number of transistors to the number of photoelectric conversion units) is reduced. Thus, for example, the pixel 11 can be miniaturized.

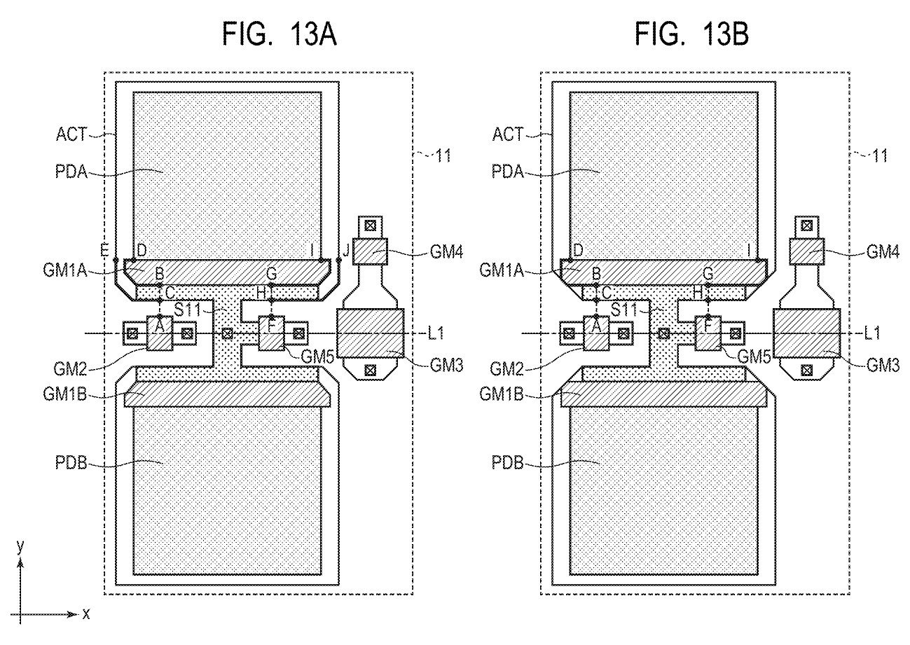

FIG. 13A is a plan view illustrating a configuration example of the pixel 11 according to the present embodiment. FIG. 13A illustrates an arrangement of gate electrodes GM1A to GM5, an N-type semiconductor region S11, and an active region ACT. The photoelectric conversion units PDA and PDB are formed in the active region ACT. The gate electrode GM1A is the gate of the transfer transistor M1A, and the gate electrode GM1B is the gate of the transfer transistor M1B. The N-type semiconductor region S11 is the drain of the transfer transistor M1A and the drain of the transfer transistor M1B, and is shared by the transfer transistor M1A and the transfer transistor M1B. The transfer transistor M1A and the transfer transistor M1B are arranged line-symmetrically with respect to a line segment L1 parallel to the x direction, the line segment L1 passing between the gate electrode GM1A and the gate electrode GM1B. That is, the gate electrode GM1A and the gate electrode GM1B are also arranged line-symmetrically with respect to the line segment L1. However, the transfer transistor M1A and the transfer transistor M1B may be arranged asymmetrically.

The reset transistor M2, the capacitance addition transistor M5, and the amplification transistor M3 are arranged side by side in the x direction. Although the reset transistor M2 and the capacitance addition transistor M5 are arranged between the gate electrode GM1A and the gate electrode GM1B, the amplification transistor M3 is arranged at a position other than between the gate electrode GM1A and the gate electrode GM1B. Such an arrangement reduces a parasitic capacitance between the amplification transistor M3 and the transfer transistors M1A and M1B. As a result, the capacitance of the floating diffusion FD is reduced, and the conversion efficiency from the charge to the voltage in the floating diffusion FD may be increased.

Next, a modification in which the arrangement of the gate electrodes GM1A and GM1B of the transfer transistors M1A and M1B and the isolation portion IS1 is modified to a similar configuration as that of the second embodiment will be described. FIG. 13B is a plan view illustrating a configuration example of the pixel 11 according to the modification of the present embodiment. While a gap is provided between the end portions of the gate electrodes GM1A and GM1B and the end portion of the active region ACT in FIG. 13A, the end portions of the gate electrodes GM1A and GM1B extend beyond the end portions of the active region ACT in FIG. 13B. Therefore, in the present modification, the paths B-D and G-I pass outside the active region ACT, that is, over the isolation portion IS1. Accordingly, the amount of dark current flowing into the photoelectric conversion unit PD can be reduced, and noise can be reduced.

Also in the present embodiment, as in the first to fourth embodiments, the photoelectric conversion device 1 capable of improving signal quality is provided.

### Sixth Embodiment

In the present embodiment, a modification in which the pixel 11 includes two selection transistors will be described. In the present embodiment, description of elements common to the first to fifth embodiments may be omitted or simplified.

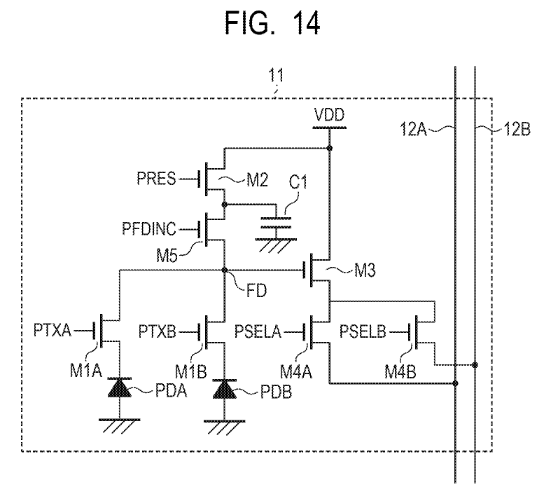

FIG. 14 is a circuit diagram illustrating a configuration example of the pixel 11 according to the present embodiment. The pixel 11 of the present embodiment has two selection transistors M4A and M4B (first selection transistor and second selection transistor). This point of the pixel 11 of the present embodiment is different from the pixel 11 of FIG. 12 of the fifth embodiment. Further, in the photoelectric conversion device 1 of the present embodiment, two output signal lines 12A and 12B (first output signal line and second output signal line) are arranged for each column.

Drains of the selection transistors M4A and M4B are connected to the source of the amplification transistor M3. A source of the selection transistor M4A is connected to the output signal line 12A, and a source of the selection transistor M4B is connected to the output signal line 12B.

The vertical scanning circuit 20 supplies a control signal PSELA to a gate of the selection transistor M4A via one signal line constituting the scanning line 13. When the selection transistor M4A is turned on according to the control signal PSELA, a signal is output from the amplification transistor M3 in the corresponding row to the output signal line 12A. In addition, the vertical scanning circuit 20 supplies a control signal PSELB to a gate of the selection transistor M4B via another signal line constituting the scanning line 13. When the selection transistor M4B is turned on according to the control signal PSELB, a signal is output from the amplification transistor M3 in the corresponding row to the output signal line 12B.

As described above, in the present embodiment, signals can be output from one pixel 11 to the two output signal lines 12A and 12B. For example, a readout method of outputting a signal from each pixel via the output signal line 12A and a readout method of adding and outputting signals of a plurality of pixels of the same color via the output signal line 12B can be performed in parallel. In this case, since the time required to read out the signals can be reduced, the speed of the imaging operation can be increased.

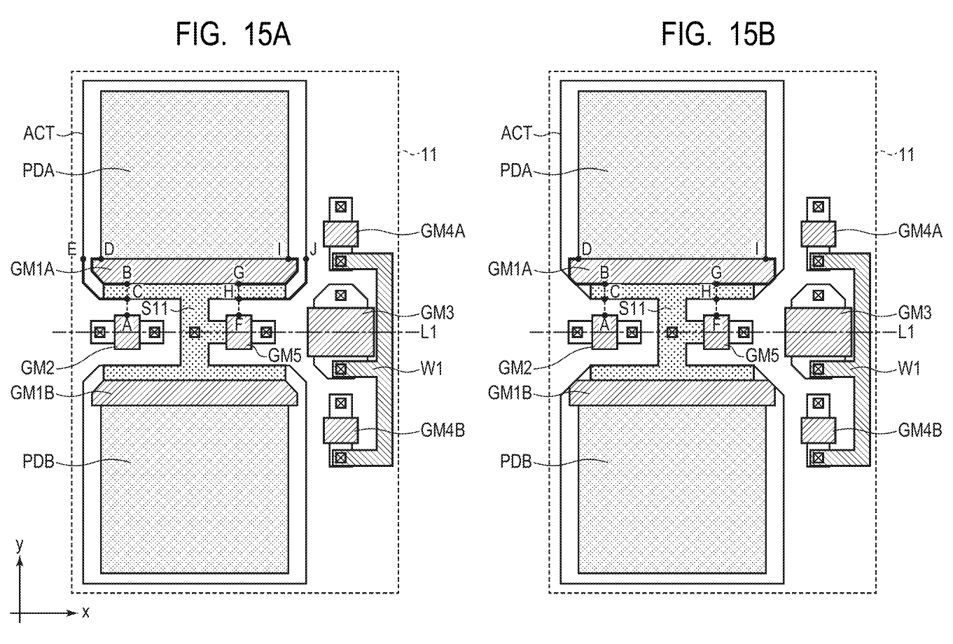

FIG. 15A is a plan view illustrating a configuration example of the pixel 11 according to the present embodiment. FIG. 15A illustrates an arrangement of gate electrodes GM1A to GM5, an N-type semiconductor region S11, an active region ACT, and a wiring W1. The gate electrode GM4A is the gate of the selection transistor M4A, and the gate electrode GM4B is the gate of the selection transistor M4B.

The selection transistor M4A, the amplification transistor M3, and the selection transistor M4B are arranged side by side in the y direction (first direction). The source of the amplification transistor M3, the drain of the selection transistor M4A, and the drain of the selection transistor M4B are connected to the wiring W1 via vias. Thus, the source of the amplification transistor M3, the drain of the selection transistor M4A, and the drain of the selection transistor M4B are electrically connected to each other.

As illustrated in FIG. 15A, in the amplification transistor M3, the source, the gate electrode GM3, and the drain are arranged side by side in the y direction. However, the source, the gate electrode GM3, and the drain may be arranged side by side in the x direction.

An end portion of the gate electrode GM4A faces an end portion of the photoelectric conversion unit PDA, and an end portion of the gate electrode GM4B faces an end portion of the photoelectric conversion unit PDB. That is, the photoelectric conversion unit PDA and the gate electrode GM4A are arranged side by side in the x direction (second direction), and the photoelectric conversion unit PDB and the gate electrode GM4B are also arranged side by side in the x direction. When the selection transistors M4A and M4B are turned on, the hole density decreases in the vicinity of the interface of the isolation portion where the gate electrodes GM4A and GM4B and the photoelectric conversion units PDA and PDB face each other. As a result, the dark current increases, and noise may occur due to the dark current flowing into the photoelectric conversion units PDA and PDB. However, by arranging the gate electrodes GM4A and GM4B and the photoelectric conversion units PDA and PDB as described above, when the selection transistors M4A and M4B are turned on, the dark current flowing into the photoelectric conversion units PDA and PDB can be made close to an equal amount. Thus, the influence of dark current on image quality can be reduced. An example of the influence of dark current on image quality is stripe-shaped fixed pattern noise. Therefore, with the above arrangement, for example, the effect of reducing the fixed pattern noise can be obtained.

Next, a modification in which an arrangement of the gate electrodes GM1A and GM1B of the transfer transistors M1A and M1B and the isolation portion IS1 is modified to a similar configuration as that of the second embodiment will be described. FIG. 15B is a plan view illustrating a configuration example of the pixel 11 according to the modification of the present embodiment. While a gap is provided between the end portions of the gate electrodes GM1A and GM1B and the end portion of the active region ACT in FIG. 15A, the end portions of the gate electrodes GM1A and GM1B extend beyond the end portions of the active region ACT in FIG. 15B. Therefore, in the present modification, the paths B-D and G-I pass outside the active region ACT, that is, over the isolation portion IS1. Accordingly, the amount of dark current flowing into the photoelectric conversion unit PD can be reduced, and noise can be reduced.

Also in the present embodiment, similarly to the first embodiment to the fifth embodiment, the photoelectric conversion device 1 capable of improving the signal quality is provided.

### Seventh Embodiment

In the present embodiment, a modification in which the source of the amplification transistor M3 is configured by two N-type semiconductor regions in the configuration of the sixth embodiment will be described. In the present embodiment, description of elements common to the first to sixth embodiments may be omitted or simplified.

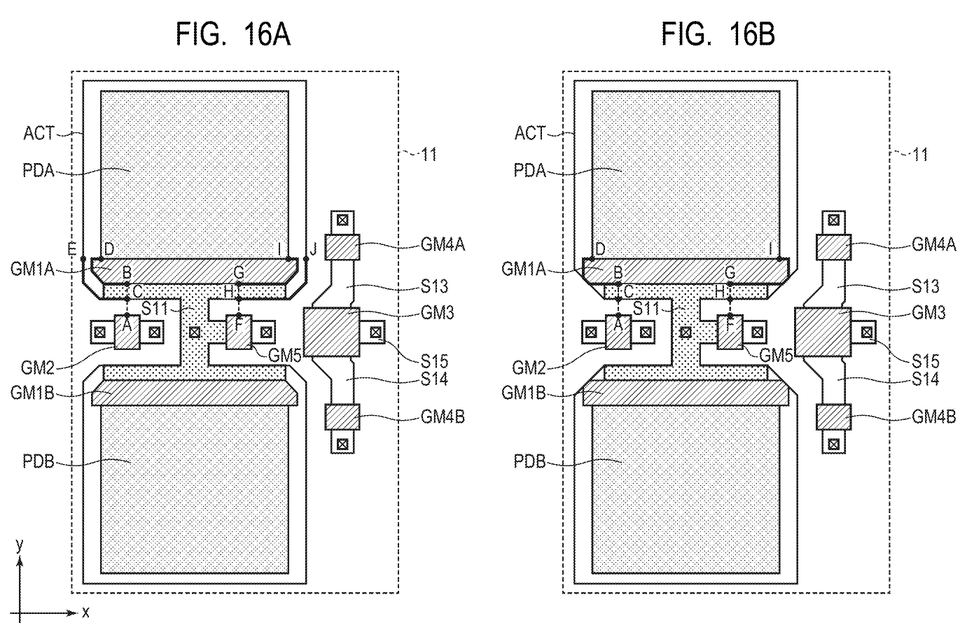

FIG. 16A is a plan view illustrating a configuration example of the pixel 11 according to the present embodiment. FIG. 16A illustrates an arrangement of gate electrodes GM1A to GM5, N-type semiconductor regions S11, S13, S14, and S15, and an active region ACT.

The N-type semiconductor region S13 (third semiconductor region) is a region that serves as the source of the amplification transistor M3 and the drain of the selection transistor M4A. The N-type semiconductor region S14 (fourth semiconductor region) is a region that serves as the source of the amplification transistor M3 and the drain of the selection transistor M4B. The N-type semiconductor region S15 is the drain of the amplification transistor M3. Thus, the same circuit configuration is realized without using the wiring W1 as illustrated in FIGS. 15A and 15B. Therefore, the wiring density in the pixel 11 is reduced, and the possibility that an unintended short circuit occurs between the wirings in the manufacturing process of the wirings is reduced. Therefore, the yield of the photoelectric conversion device 1 can be improved.

Next, a modification in which an arrangement of the gate electrodes GM1A and GM1B of the transfer transistors M1A and M1B and the isolation portion IS1 is modified to a similar configuration as that of the second embodiment will be described. FIG. 16B is a plan view illustrating a configuration example of the pixel 11 according to the modification of the present embodiment. While a gap is provided between the end portions of the gate electrodes GM1A and GM1B and the end portion of the active region ACT in FIG. 16A, the end portions of the gate electrodes GM1A and GM1B extend beyond the end portions of the active region ACT in FIG. 16B. Therefore, in the present modification, the path G-I passes outside the active region ACT, that is, over the isolation portion IS1. Accordingly, the amount of dark current flowing into the photoelectric conversion unit PD can be reduced, and noise can be reduced.

Also in the present embodiment, as in the first to sixth embodiments, the photoelectric conversion device 1 capable of improving signal quality is provided.

### Eighth Embodiment

In the present embodiment, a modification in which the pixel 11 includes four photoelectric conversion units and four transfer transistors will be described. Further, in the present embodiment, the microlens ML is arranged not at the first face F1 side but at the second face F2 side. In the present embodiment, description of elements common to the first to seventh embodiments may be omitted or simplified.

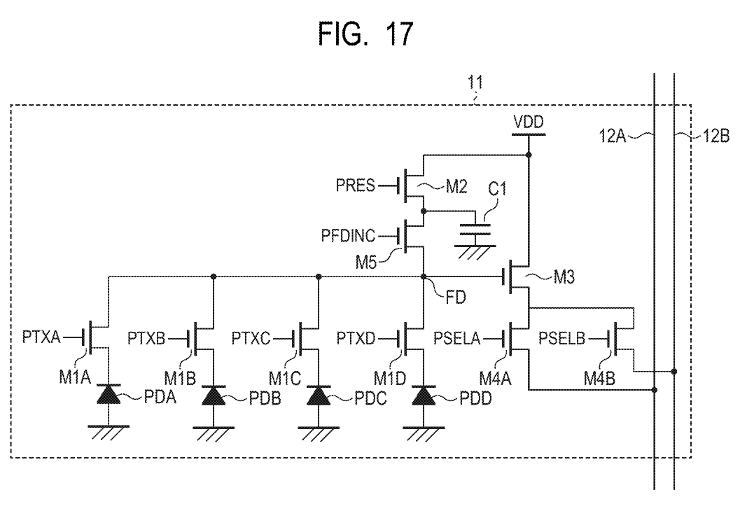

FIG. 17 is a circuit diagram illustrating a configuration example of the pixel 11 according to the present embodiment. The pixel 11 of the present embodiment includes four photoelectric conversion units PDA, PDB, PDC, and PDD and four transfer transistors M1A, M1B, M1C, and M1D. This point of the pixel 11 of the present embodiment is different from the pixel 11 of FIG. 14 of the sixth embodiment. Hereinafter, the photoelectric conversion units PDC and PDD (third photoelectric conversion unit and fourth photoelectric conversion unit) and the transfer transistors M1C and M1D (third transfer transistor and fourth transfer transistor) added to FIG. 14 of the sixth embodiment will be mainly described.

Anodes of the photoelectric conversion units PDC and PDD are connected to the ground line having the ground potential. A cathode of the photoelectric conversion unit PDC is connected to a source of the transfer transistor M1C, and a cathode of the photoelectric conversion unit PDD is connected to a source of the transfer transistor M1D. Drains of the transfer transistors M1C and M1D are connected to the source of the capacitance addition transistor M5 and the gate of the amplification transistor M3. A connection node between the drains of the transfer transistors M1A, M1B, M1C, and M1D, the source of the capacitance addition transistor M5, and the gate of the amplification transistor M3 is the floating diffusion FD.

The vertical scanning circuit 20 supplies a control signal PTXC to a gate of the transfer transistor M1C via one signal line constituting the scanning line 13. When the transfer transistor M1C is turned on according to the control signal PTXC, charges accumulated in the photoelectric conversion unit PDC is transferred to the floating diffusion FD. Further, the vertical scanning circuit 20 supplies a control signal PTXD to a gate of the transfer transistor M1D via another signal line constituting the scanning line 13. When the transfer transistor M1D is turned on according to the control signal PTXD, charges accumulated in the photoelectric conversion unit PDD is transferred to the floating diffusion FD.

As described above, in the present embodiment, the four photoelectric conversion units PDA, PDB, PDC, and PDD share the reset transistor M2, the amplification transistor M3, the selection transistors M4A and M4B, and the capacitance addition transistor M5. That is, the number of transistors per photoelectric conversion unit is further reduced.

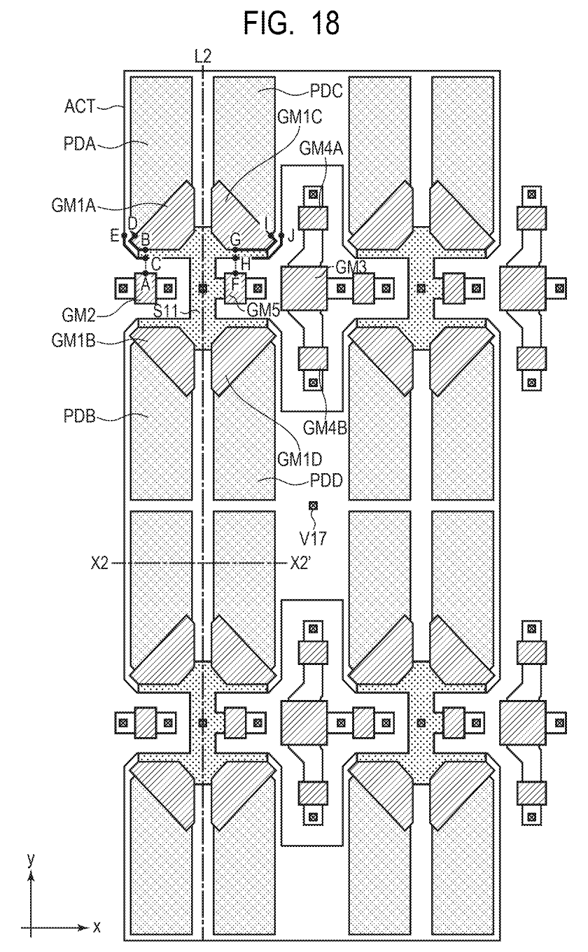

FIG. 18 is a plan view illustrating a configuration example of the pixel 11 according to the present embodiment. FIG. 18 illustrates an arrangement of gate electrodes GM1A to GM5, an N-type semiconductor region S11, a via V17, and an active region ACT. The gate electrode GM1C is the gate of the transfer transistor M1C, and the gate electrode GM1D is the gate of the transfer transistor M1D. The N-type semiconductor region S11 is the drain of the transfer transistors M1A, M1B, M1C, and M1D, and is shared by the four transfer transistors M1A, M1B, M1C, and M1D. The via V17 is connected to the ground line that supplies the ground potential to a P-type semiconductor region that separates photoelectric conversion units.

The photoelectric conversion unit PDA and the photoelectric conversion unit PDC are arranged line-symmetrically with respect to a line segment L2 parallel to the y direction. Accordingly, a focus detection of a phase difference detection method in the x direction can be performed by a signal based on charges accumulated in the photoelectric conversion unit PDA and a signal based on charges accumulated in the photoelectric conversion unit PDC. The photoelectric conversion unit PDB and the photoelectric conversion unit PDD are arranged line-symmetrically with respect to the line segment L2. Accordingly, the focus detection of the phase difference detection method in the x direction can be performed by a signal based on charges accumulated in the photoelectric conversion unit PDB and a signal based on charges accumulated in the photoelectric conversion unit PDD.

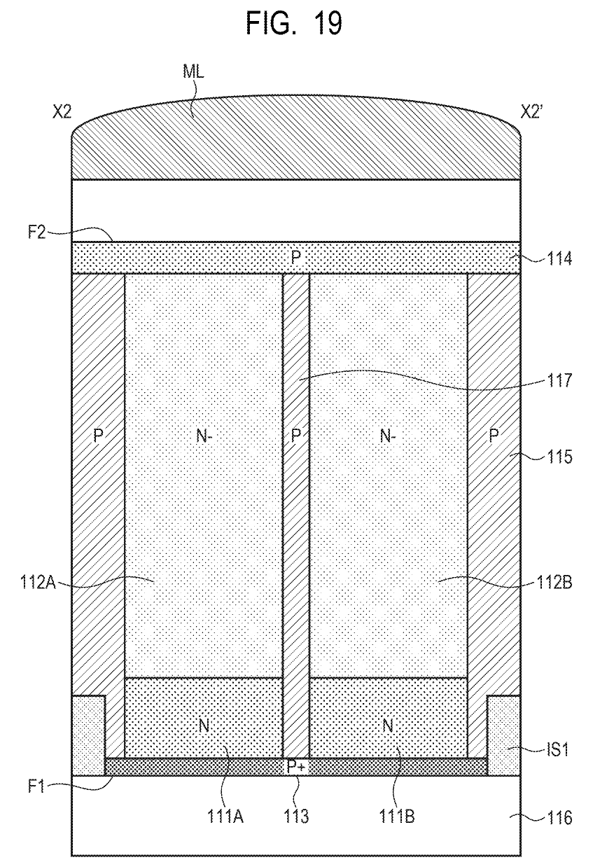

FIG. 19 is a cross-sectional view illustrating a configuration example of the pixel 11 according to the present embodiment. FIG. 19 illustrates a cross section taken along line X2-X2' in FIG. 18. A wiring layer 116 is arranged over a first face F1 which is a front face of the semiconductor substrate in which the photoelectric conversion device 1 is formed. A second face F2 opposite to the first face F1 is a back face of the semiconductor substrate. A microlens ML is arranged over the second face F2. That is, the photoelectric conversion device 1 of the present embodiment is a backside illumination type that receives light incident from the second face F2.

N-type semiconductor regions 111A and 111B and N-type semiconductor regions 112A and 112B are formed in portions of the photoelectric conversion units PDA and PDC in the semiconductor substrate. The N-type semiconductor region 111A is arranged closer to the first face F1 than the N-type semiconductor region 112A, and the N-type semiconductor region 111B is arranged closer to the first face F1 than the N-type semiconductor region 112B. Peak concentrations of impurity in the N-type semiconductor regions 111A and 111B are higher than peak concentrations of impurity in the N-type semiconductor regions 112A and 112B. A P-type semiconductor region 117 is arranged between the N-type semiconductor region 111A and the N-type semiconductor region 111B and between the N-type semiconductor region 112A and the N-type semiconductor region 112B. The P-type semiconductor region 117 is an isolation portion that separates the N-type semiconductor region 111A and the N-type semiconductor region 111B and separates the N-type semiconductor region 112A and the N-type semiconductor region 112B.

A common microlens ML (first microlens) is arranged over each of the photoelectric conversion units PDA and PDC, and light that has passed through different pupil regions of the optical system enters each of the photoelectric conversion units PDA and PDC. In addition, another common microlenses (second microlenses) is arranged over the photoelectric conversion units PDB and PDD, and light that has passed through different pupil regions of the optical system enters each of the photoelectric conversion units PDB and PDD. With these configurations, signals that can be suitably used for the focus detection by the phase difference detection method are generated.

In the present embodiment, the backside illumination type in which the photoelectric conversion device receives incident light from the second face F2 different from the first face F1 on which the wiring layer 116 is arranged is employed. Accordingly, the incident light to the second face F2 enters the photoelectric conversion units PDA, PDB, PDC, and PDD without being reflected by the wiring in the wiring layer 116, and signals corresponding to the incident light are generated. Therefore, the sensitivity of the photoelectric conversion units PDA, PDB, PDC, and PDD can be improved.

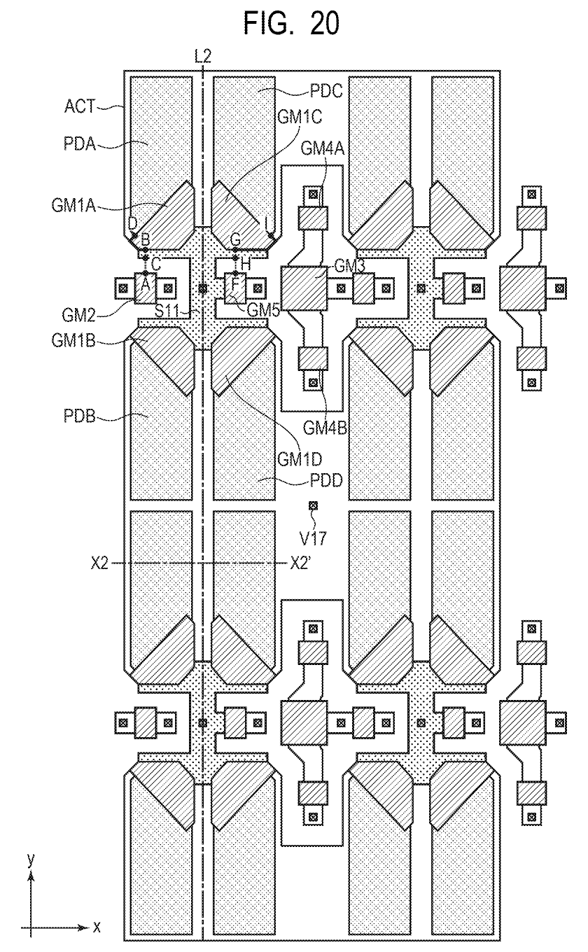

Next, a modification in which an arrangement of the gate electrodes GM1A, GM1B, GM1C, and GM1D of the transfer transistors M1A, M1B, M1C, and M1D and the isolation portion IS1 is modified to a similar configuration as that of the second embodiment will be described. FIG. 20 is a plan view illustrating a configuration example of the pixel 11 according to a modification of the present embodiment. While a gap is provided between the end portions of the gate electrodes GM1A and GM1C and the end portion of the active region ACT in FIG. 18, the end portions of the gate electrodes GM1A and GM1C extend beyond the end portion of the active region ACT in FIG. 20. Therefore, in the present modification, the paths B-D and G-I pass outside the active region ACT, that is, over the isolation portion IS1. Accordingly, the amount of dark current flowing into the photoelectric conversion units PDA and PDC can be reduced, and noise can be reduced. The same applies to the gate electrodes GM1B and GM1D, and the amount of dark current flowing into the photoelectric conversion units PDB and PDD can be reduced, and noise can be reduced.

Also in the present embodiment, as in the first to seventh embodiments, the photoelectric conversion device 1 capable of improving signal quality is provided.

### Ninth Embodiment

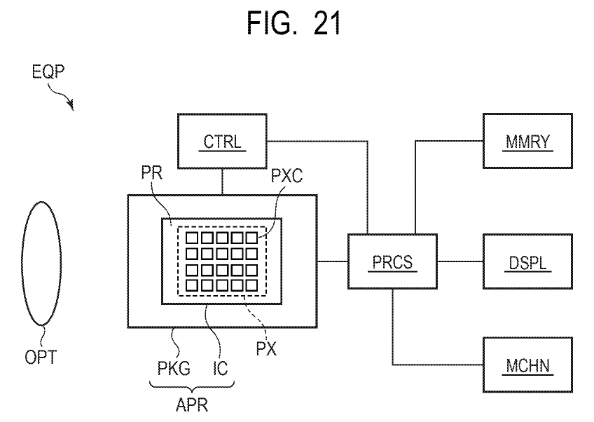

Equipment according to a ninth embodiment will be described with reference to FIG. 21. FIG. 21 is a block diagram illustrating a schematic configuration of equipment according to the present embodiment.

FIG. 21 is a schematic diagram illustrating equipment EQP including a photoelectric conversion device APR. The photoelectric conversion device APR has the function of the photoelectric conversion device 1 according to the first to eighth embodiments. All or part of the photoelectric conversion device APR is a semiconductor device IC. The photoelectric conversion device APR of this example can be used as, for example, an image sensor, an auto focus (AF) sensor, a photometric sensor, a ranging sensor, or the like. The semiconductor device IC has a pixel area PX in which pixel circuits PXC each including photoelectric conversion unit are arranged in a matrix. The semiconductor device IC may have a peripheral area PR around the pixel area PX. Circuits other than the pixel circuits can be arranged in the peripheral area PR.

The photoelectric conversion device APR may have a structure (stacked chips structure) in which a first semiconductor chip provided with a plurality of photoelectric conversion units and a second semiconductor chip provided with a peripheral circuit are stacked. Each of the peripheral circuits in the second semiconductor chip may be a column circuit corresponding to a pixel column of the first semiconductor chip. Each of the peripheral circuits in the second semiconductor chip may be a matrix circuit corresponding to a pixel or a pixel block in the first semiconductor chip. For the connection between the first semiconductor chip and the second semiconductor chip, a through electrode (TSV), an inter-chip wiring by direct bonding of a conductor such as copper, a connection by a micro bump between chips, a connection by wire bonding, or the like can be employed.

The photoelectric conversion device APR may include a package PKG for mounting the semiconductor device IC in addition to the semiconductor device IC. The package PKG may include a base body to which the semiconductor device IC is fixed, a lid such as glass facing the semiconductor device IC, and a connection member such as a bonding wire or a bump for connecting a terminal provided on the base body and a terminal provided on the semiconductor device IC.

The equipment EQP may further include at least one of an optical device OPT, a control device CTRL, a processing device PRCS, a display device DSPL, a storage device MMRY, and a mechanical device MCHN. The optical device OPT corresponds to the photoelectric conversion device APR, and is, for example, a lens, a shutter, or a mirror. The control device CTRL controls the photoelectric conversion device APR, and is, for example, a semiconductor device such as an ASIC.

The processing device PRCS processes a signal output from the photoelectric conversion device APR, and constitutes an analog front end (AFE) or a digital front end (DFE). The processing device PRCS is a semiconductor device such as a central processing unit (CPU) or an application specific integrated circuit (ASIC). The display device DSPL is an EL display device, a liquid crystal display device, or the like that displays information (image) obtained by the photoelectric conversion device APR. The storage device MMRY is a magnetic device, a semiconductor device, or the like that stores information (image) obtained by the photoelectric conversion device APR. The storage device MMRY is a volatile memory such as an SRAM or a DRAM, or a nonvolatile memory such as a flash memory or a hard disk drive.

The mechanical device MCHN includes a movable portion or a propulsion portion such as a motor or an engine. In the equipment EQP, a signal output from the photoelectric conversion device APR is displayed on the display device DSPL or transmitted to the outside by a communication device (not illustrated) included in the equipment EQP. Therefore, the equipment EQP may further include a storage device MMRY and a processing device PRCS separately from the storage circuit unit and the arithmetic circuit unit included in the photoelectric conversion device APR. The mechanical device MCHN may be controlled based on a signal output from the photoelectric conversion device APR.

The equipment EQP illustrated in FIG. 21 may be an electronic device such as an information terminal (for example, a smartphone and a wearable terminal) having a photographing function, a camera (For example, an interchangeable lens camera, a compact camera, a video camera, and a surveillance camera), or the like. The mechanical device MCHN in the camera may drive parts of the optical device OPT for zooming, focusing, and shutter operation. Also, the equipment EQP may be a transport device (movable body) such as a vehicle, a ship, a drone, or an airplane. The equipment EQP may be a medical device such as an endoscope or a CT scanner. The equipment EQP may be a measurement device such as a ranging sensor, an analysis device such as an electron microscope, an office device such as a copier, or an industrial device such as a robot.

The mechanical device MCHN in the transport device may be used as a movable device. The equipment EQP as a transport device is suitable for transporting the photoelectric conversion device APR, or for assisting and/or automating driving (manipulation) by an imaging function. The processing device PRCS for assisting and/or automating driving (manipulation) may perform processing for operating the mechanical device MCHN as a movable device based on information obtained by the photoelectric conversion device APR.

According to the first to eighth embodiments, signal acquisition can be performed satisfactorily. Therefore, the photoelectric conversion device APR according to the first to eighth embodiments may provide a high value to a designer, a manufacturer, a seller, a purchaser, and/or a user thereof. Therefore, when the photoelectric conversion device APR is mounted on the equipment EQP, the value of the equipment EQP may also be increased. Therefore, in manufacturing and selling the equipment EQP, it is advantageous to determine the mounting of the photoelectric conversion device APR of the present embodiment on the equipment EQP in order to increase the value of the equipment EQP. Here, increasing the value corresponds to at least one of adding a function, improving performance, improving characteristics, improving reliability, improving manufacturing yield, reducing environmental load, reducing cost, reducing size, and reducing weight.

For example, by mounting the photoelectric conversion device APR in a transport device, it is possible to obtain excellent performance when photographing outside the transport device or measuring an external environment. Therefore, in manufacturing and selling the transport device, it is advantageous to determine the mounting of the photoelectric conversion device APR according to the present embodiment on the transport device in order to improve the performance of the transport device itself. In particular, the photoelectric conversion device APR is suitable for a transport device that performs driving support and/or automatic driving of the transport device using information obtained by the photoelectric conversion device APR.

### Tenth Embodiment

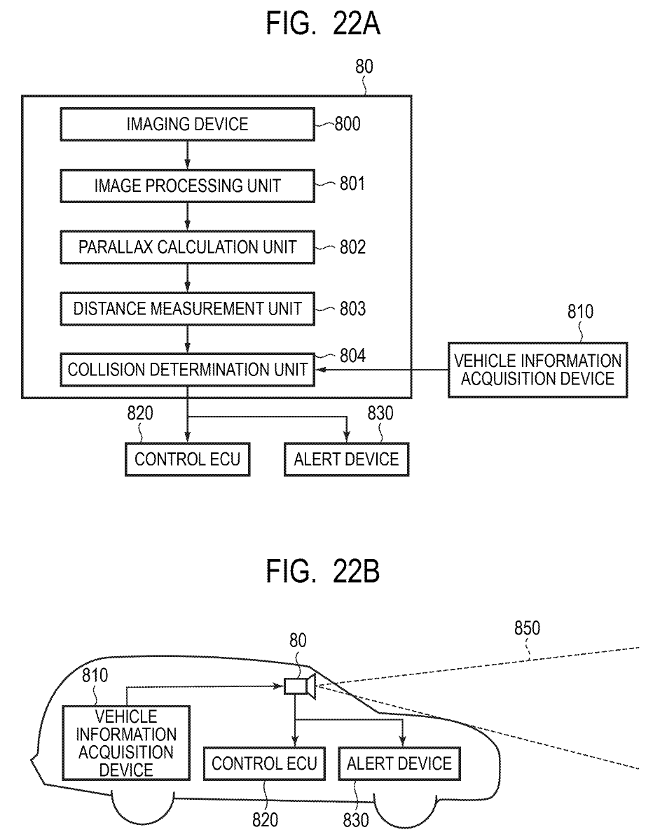

FIGS. 22A and 22B are block diagrams of equipment relating to the vehicle-mounted camera according to the present embodiment. FIGS. 22A and 22B illustrate an example in which the photoelectric conversion device is applied to a movable body such as a vehicle. The equipment 80 includes an imaging device 800 (an example of the photoelectric conversion device) and a signal processing device (processing device) that processes a signal from the imaging device 800. The equipment 80 includes an image processing unit 801 that performs image processing on a plurality of pieces of image data acquired by the imaging device 800, and a parallax calculation unit 802 that calculates parallax (phase difference of parallax images) from the plurality of pieces of image data acquired by the equipment 80.

Here, the equipment 80 may include an optical system (not illustrated) that guides light to the imaging device 800. The optical system may include, for example, a lens, a shutter, and a mirror. A plurality of photoelectric conversion units substantially conjugate to the pupil of the optical system may be arranged in a pixel included in the imaging device 800. For example, a plurality of photoelectric conversion units are arranged corresponding to one microlens. The plurality of photoelectric conversion units may receive light fluxes transmitted through different positions of the pupil of the optical system. Thus, the imaging device 800 outputs a plurality of pieces of image data respectively corresponding to the light fluxes transmitted through different positions of the pupil of the optical system. Then, the parallax calculation unit 802 may calculate the parallax using the plurality of pieces of image data being output.

The equipment 80 includes a distance measurement unit 803 that calculates a distance to an object based on the calculated parallax, and a collision determination unit 804 that determines whether or not there is a possibility of collision based on the calculated distance. Here, the parallax calculation unit 802 and the distance measurement unit 803 are examples of a distance information acquisition unit that acquires distance information to the object. That is, the distance information is information on a parallax, a defocus amount, a distance to the object, and the like. The collision determination unit 804 may determine the possibility of collision using any of these pieces of distance information. Note that the distance information may be acquired using a time of flight (ToF) technique. The distance information acquisition unit may be realized by dedicatedly designed hardware or software modules. Further, it may be realized by a field programmable gate array (FPGA), an application specific integrated circuit (ASIC) or a combination thereof.

The equipment 80 is connected to the vehicle information acquisition device 810, and can obtain vehicle information such as a vehicle speed, a yaw rate, and a steering angle. Further, the equipment 80 is connected to a control ECU 820 which is a control device that outputs a control signal for generating a braking force to the vehicle based on the determination result of the collision determination unit 804. The equipment 80 is also connected to an alert device 830 that issues an alert to the driver based on the determination result of the collision determination unit 804. For example, when the collision possibility is high as the determination result of the collision determination unit 804, the control ECU 820 performs vehicle control to avoid collision or reduce damage by braking, returning an accelerator, suppressing engine output, or the like. The alert device 830 alerts the user by sounding an alarm such as a sound, displaying alert information on a screen of a car navigation system or the like, or giving vibration to a seat belt or a steering wheel. The equipment 80 functions as a control unit that controls the operation of controlling the vehicle as described above.

In the present embodiment, an image of the periphery of the vehicle, for example, the front or the rear is captured by the equipment 80. FIG. 22B illustrates equipment in a case where an image is captured in front of the vehicle (image capturing range 850). The vehicle information acquisition device 810 as the imaging control unit sends an instruction to the equipment 80 or the imaging device 800 to perform the imaging operation. With such a configuration, the accuracy of distance measurement can be further improved.

Although the example of control for avoiding a collision to another vehicle has been described above, the embodiment is applicable to automatic driving control for following another vehicle, automatic driving control for not going out of a traffic lane, or the like. Furthermore, the equipment is not limited to a vehicle such as an automobile and can be applied to a movable body (movable apparatus) such as a ship, an airplane, a satellite, an industrial robot and a consumer use robot, or the like, for example. In addition, the equipment can be widely applied to equipment which utilizes object recognition or biometric authentication, such as an intelligent transportation system (ITS), a surveillance system, or the like without being limited to movable bodies.

### Other Embodiments

The present disclosure is not limited to the above embodiments, and various modifications are possible. For example, an example in which some of the configurations of any one of the embodiments are added to other embodiments or an example in which some of the configurations of any one of the embodiments are replaced with some of the configurations of other embodiments are also embodiments of the present disclosure.

The embodiments described above can be appropriately modified without departing from the technical idea. Note that the disclosure of the present specification includes not only the matters described in the present specification but also all matters that can be grasped from the present specification and the drawings attached to the present specification. Also, the disclosure of the present specification includes a complementary set of the concepts described in the present specification. In other words, for example, when there is a description of "A is greater than B" in the present specification, it can be said that the description of "A is not greater than B" is disclosed in the present specification even when the description of "A is not greater than B" is omitted. This is because it is assumed that the case where "A is not greater than B" is considered when "A is greater than B" is described.

Embodiment(s) of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

It should be noted that the above-described embodiments are merely specific examples for carrying out the present disclosure, and the technical scope of the present disclosure should not be interpreted in a limited manner by these embodiments. That is, the present disclosure can be implemented in various forms without departing from the technical idea or the main features thereof.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-068396, filed Apr. 17, 2025, which is hereby incorporated by reference herein in its entirety.

What is claimed is:

1. A photoelectric conversion device comprising:
a semiconductor substrate;
a first photoelectric conversion unit formed in an active region of the semiconductor substrate;
a plurality of transistors formed in the semiconductor substrate; and
a floating diffusion formed in the semiconductor substrate,
wherein the plurality of transistors include a first transfer transistor configured to transfer charges from the first photoelectric conversion unit to the floating diffusion, and a switching transistor that is electrically connected to the floating diffusion and is different from the first transfer transistor,
wherein in a plan view with respect to the semiconductor substrate, a part of an outer edge of a gate electrode of the first transfer transistor is in contact with a part of an outer edge of the first photoelectric conversion unit,
wherein in the plan view, when an intersection point of a straight line connecting the gate electrode of the first transfer transistor and a gate electrode of the switching transistor at a shortest distance and an end portion of the gate electrode of the switching transistor is defined as a first point, and when an intersection point of the straight line and an end portion of the gate electrode of the first transfer transistor is defined as a second point, a third point is between the first point and the second point, the third point being an end portion of a first semiconductor region constituting a main electrode of the first transfer transistor on a side of the floating diffusion, and being an end portion of the active region,
wherein in the plan view, when an intersection point of the end portion of the gate electrode of the first transfer transistor and an end portion of the first photoelectric conversion unit is defined as a fourth point, and when a shortest portion between the second point and the fourth point in the outer edge of the gate electrode of the first transfer transistor is defined as a first outer edge portion, the first outer edge portion does not overlap with an isolation portion that is arranged outside the active region and that electrically separates the first photoelectric conversion unit from other elements, and
wherein in the plan view, when a point closest to the fourth point in an end portion of the active region is defined as a fifth point, and when a shortest portion between the third point and the fifth point in the outer edge of the active region is defined as a second outer edge portion, a shortest distance between the first outer edge portion and the second outer edge portion is shorter than a distance between the second point and the third point.

2. A photoelectric conversion device comprising:
a semiconductor substrate;
a first photoelectric conversion unit formed in an active region of the semiconductor substrate;
a plurality of transistors formed in the semiconductor substrate; and
a floating diffusion formed in the semiconductor substrate,
wherein the plurality of transistors include a first transfer transistor configured to transfer charges from the first photoelectric conversion unit to the floating diffusion, and a switching transistor that is electrically connected to the floating diffusion and is different from the first transfer transistor,
wherein in a plan view with respect to the semiconductor substrate, a part of an outer edge of a gate electrode of the first transfer transistor overlaps a part of an outer edge of the first photoelectric conversion unit,
wherein in the plan view, when an intersection point of a straight line connecting the gate electrode of the first transfer transistor and a gate electrode of the switching transistor at a shortest distance and an end portion of the gate electrode of the switching transistor is defined as a first point, and when an intersection point of the straight line and an end portion of the gate electrode of the first transfer transistor is defined as a second point, a third point is between the first point and the second point, the third point being an end portion of a first semiconductor region constituting a main electrode of the first transfer transistor on a side of the floating diffusion, and being an end portion of the active region, and
wherein in the plan view, when an intersection point of the end portion of the gate electrode of the first transfer transistor and an end portion of the first photoelectric conversion unit is defined as a fourth point, and when a shortest portion between the second point and the fourth point in the outer edge of the gate electrode of the first transfer transistor is defined as a first outer edge portion, at least a part of the first outer edge portion overlaps with an isolation portion that is arranged outside the active region and that electrically separates the first photoelectric conversion unit from other elements.

3. The photoelectric conversion device according to claim 1,
wherein in the plan view, a second semiconductor region is arranged adjacent to the first semiconductor region,
wherein the first semiconductor region is of a first conductivity type, and
wherein the second semiconductor region is of a second conductivity type.

4. The photoelectric conversion device according to claim 1,
wherein in the plan view, a second semiconductor region is arranged adjacent to the first semiconductor region,
wherein the first semiconductor region and the second semiconductor region are of a first conductivity type, and
wherein a peak concentration of impurity in the second semiconductor region is lower than a peak concentration of impurity in the first semiconductor region.

5. The photoelectric conversion device according to claim 1, wherein the switching transistor resets a potential of the floating diffusion by being turned on.

6. The photoelectric conversion device according to claim 1 further comprising a capacitive element,
wherein the switching transistor electrically connects the floating diffusion and the capacitive element by being turned on.

7. The photoelectric conversion device according to claim 1 further comprising a second photoelectric conversion unit formed in the semiconductor substrate,
wherein the plurality of transistors further include a second transfer transistor configured to transfer charges from the second photoelectric conversion unit to the floating diffusion.

8. The photoelectric conversion device according to claim 7, wherein the first photoelectric conversion unit and the second photoelectric conversion unit are arranged in a same active region.

9. The photoelectric conversion device according to claim 7, wherein the first semiconductor region constitutes a main electrode of the second transfer transistor on a side of the floating diffusion.

10. The photoelectric conversion device according to claim 7, wherein in the plan view, the gate electrode of the first transfer transistor and a gate electrode of the second transfer transistor are arranged line-symmetrically to each other.

11. The photoelectric conversion device according to claim 7 further comprising a capacitive element,
wherein the plurality of transistors include, as the switching transistor, a reset transistor configured to reset a potential of the floating diffusion by being turned on, and a capacitance addition transistor configured to electrically connect the floating diffusion and the capacitive element by being turned on,
wherein the plurality of transistors further include an amplification transistor configured to output a signal according to the potential of the floating diffusion, and
wherein in the plan view, the reset transistor and the capacitance addition transistor are arranged between the gate electrode of the first transfer transistor and a gate electrode of the second transfer transistor.

12. The photoelectric conversion device according to claim 11, wherein in the plan view, the amplification transistor is not arranged between the gate electrode of the first transfer transistor and the gate electrode of the second transfer transistor.

13. The photoelectric conversion device according to claim 7 further comprising a first output signal line and a second output signal line,
wherein the plurality of transistors further include an amplification transistor configured to output a signal according to a potential of the floating diffusion, a first selection transistor configured to output a signal from the amplification transistor to the first output signal line by being turned on, and a second selection transistor configured to output a signal from the amplification transistor to the second output signal line by being turned on,
wherein in the plan view, the first selection transistor and the second selection transistor are arranged side by side in a first direction so as to sandwich the amplification transistor therebetween,
wherein in the plan view, the first photoelectric conversion unit and the first selection transistor are arranged side by side in a second direction different from the first direction, and
wherein in the plan view, the second photoelectric conversion unit and the second selection transistor are arranged side by side in the second direction.

14. The photoelectric conversion device according to claim 13,
wherein a third semiconductor region and a fourth semiconductor region are arranged in the semiconductor substrate,
wherein the third semiconductor region constitutes a main electrode of the first selection transistor and a main electrode of the amplification transistor, and
wherein the fourth semiconductor region constitutes a main electrode of the second selection transistor and a main electrode of the amplification transistor.

15. The photoelectric conversion device according to claim 13, wherein a main electrode of the first selection transistor, a main electrode of the second selection transistor, and a main electrode of the amplification transistor are electrically connected to each other via a wiring arranged over the semiconductor substrate.

16. The photoelectric conversion device according to claim 7 further comprising:
a first microlens and a second microlens; and
a third photoelectric conversion unit and a fourth photoelectric conversion unit each formed in the semiconductor substrate,
wherein the plurality of transistors further include a third transfer transistor configured to transfer charges from the third photoelectric conversion unit to the floating diffusion, and a fourth transfer transistor configured to transfer charges from the fourth photoelectric conversion unit to the floating diffusion,
wherein the first microlens is arranged to guide incident light to the first photoelectric conversion unit and the third photoelectric conversion unit, and
wherein the second microlens is arranged to guide incident light to the second photoelectric conversion unit and the fourth photoelectric conversion unit.

17. The photoelectric conversion device according to claim 16, wherein the first semiconductor region constitutes a main electrode of the third transfer transistor on a side of the floating diffusion, and constitutes a main electrode of the fourth transfer transistor on a side of the floating diffusion.

18. The photoelectric conversion device according to claim 1,
wherein the semiconductor substrate has a first face and a second face opposite to the first face,
wherein a wiring layer is arranged on the first face, and
wherein the first photoelectric conversion unit has sensitivity to light incident on the second face.

19. Equipment comprising:
the photoelectric conversion device according to claim 1; and
at least any one of:
an optical device adapted for the photoelectric conversion device,
a control device configured to control the photoelectric conversion device,
a processing device configured to process a signal output from the photoelectric conversion device,
a display device configured to display information obtained by the photoelectric conversion device,
a storage device configured to store information obtained by the photoelectric conversion device, and
a mechanical device configured to operate based on information obtained by the photoelectric conversion device.

20. The equipment according to claim 19, wherein the processing device acquires information on a distance from the photoelectric conversion device to an object.
